(19) United States
(12) Patent Application Publication
(10) Pub. No.: US 2025/0294774 A1
(43) Pub. Date: Sep. 18, 2025

(54) RECONFIGURABLE CO-LOCATED LONG- AND SHORT-TERM MEMORY SYSTEMS

(71) Applicants: Purdue Research Foundation, West Lafayette, IN (US); University of Mississippi, University, MS (US)

(72) Inventors: Raisul Islam, West Lafayette, IN (US); Md Sakib Hasan, Oxford, MS (US)

(73) Assignees: Purdue Research Foundation, West Lafayette, IN (US); University of Mississippi, University, MS (US)

(21) Appl. No.: 19/079,243

(22) Filed: Mar. 13, 2025

Related U.S. Application Data
(60) Provisional application No. 63/564,704, filed on Mar. 13, 2024.

(51) Int. Cl. H10B 51/30; G11C 11/22

(52) U.S. Cl. CPC H10B 51/30; G11C 11/223; G11C 11/2273; G11C 11/2275

(57) ABSTRACT

A cell capable of having long-term and short-term plasticity, includes a source terminal, a drain terminal, and a gate terminal each coupled to a semiconductor layer, wherein the semiconductor layer is a doped semiconductor layer or an undoped semiconductor layer, a ferroelectric dielectric layer disposed between the gate terminal and the semiconductor layer, and at least one diffusion metal layer disposed between the drain terminal or the source terminal and the semiconductor layer, wherein the at least one diffusion metal layer provides short-term plasticity in addition to the long-term plasticity provided by the ferroelectric layer.

### CROSS-REFERENCE TO RELATED APPLICATIONS

The present non-provisional patent application is related to and claims the priority benefit of U.S. Provisional Patent Application Ser. 63/564,704, filed Mar. 13, 2024, the contents of which are hereby incorporated by reference in its entirety into the present disclosure.

### STATEMENT REGARDING GOVERNMENT FUNDING

None.

### TECHNICAL FIELD

The present disclosure generally relates to devices with plasticity and in particular to device usable as having both long-term and short-term plasticity.

### BACKGROUND

This section introduces aspects that may help facilitate a better understanding of the disclosure. Accordingly, these statements are to be read in this light and are not to be understood as admissions about what is or is not prior art.

In the present disclosure, the term memory and plasticity are used interchangeably both intended to refer to a characteristics of a device to be able to hold information, either based on a long-term duration, or based on a short-term duration. For abundant data computing, a critical component is non-volatile memory that has faster read/write, low energy switching, scalability, and back end of line (BEOL) compatibility to bring fine-grained connectivity between logic and memory. Among many emerging non-volatile memory candidates for this purpose, the ferroelectric (FE) memories are promising owing to their low energy (about 100 fJ) and fast switching (about 10 ns). Renewed interest in FE memories has grown following the 2011 report of the ferroelectric effect in doped-HfO₂, a CMOS process friendly material. FE memories in general utilize the switching of the permanent electric polarization. Referring to FIG. 1, which is a structural schematic of a device known in the prior art, a prior art transistor device is shown in which the polarization and switching is shown. As seen in this figure, the polarization switching results in the switching of the polarization charge at the surfaces of the FE film in Ferroelectric Field Effect Transistor (FeFET) used as a gate dielectric. The FeFET utilizes the partial switching of the polarization domain in a ferroelectric thin film to gradually tune the threshold voltage (VT) of the underlying FET channel (the area under the ferroelectric dielectric layer through which current flows). This results in the gradual tuning of the drain-to-source conductance when a voltage pulse train is applied to the gate. Therefore, FeFET having a FE gate dielectric stack can work as an analog non-volatile memory where multi-level data can be stored as programmable channel conductance through V_{T} programming. This mechanism of storing data embodies the long-term memory since the data is stored even if the device is not powered.

In addition to long-term memory, short-term memory is also needed for various types of computing, e.g., reservoir computing. Short-term memory in the present disclosure refers to a memory that holds a value but only during a time-period as the ability of the memory to hold the value decays with time.

However, no structure is known that can effectively provide both a long-term memory and a short-term memory and be interchangeable in their use as memory. Furthermore, no interdependency between such classes of memory is known, such that use of a memory as long-term memory would affect operation of the short-term memory, which is an important quality when performing various computing, e.g., reservoir computing.

Therefore, there is an unmet need for a novel structure that can provide both a long-term memory and a short-term memory in the same device, with interdependencies between such classes of memory.

### SUMMARY

A cell capable of having long-term and short-term plasticity is disclosed. The cell includes a source terminal, a drain terminal, and a gate terminal each coupled to a semiconductor layer. The semiconductor layer is a doped semiconductor layer or an undoped semiconductor layer. The cell further includes a ferroelectric dielectric layer disposed between the gate terminal and the semiconductor layer. The cell additionally includes at least one diffusion metal layer disposed between the drain terminal or the source terminal and the semiconductor layer. The at least one diffusion metal layer provides short-term plasticity in addition to the long-term plasticity provided by the ferroelectric layer.

A system for short-term and long-term plasticity is also disclosed. The system includes one or more cells, each capable of having long-term and short-term plasticity. Each of the one or more cells includes a source terminal, a drain terminal, and a gate terminal each coupled to a semiconductor layer, wherein the semiconductor layer is a doped semiconductor layer or an undoped semiconductor layer, a ferroelectric dielectric layer disposed between the gate terminal and the semiconductor layer, and at least one diffusion metal layer disposed between the drain terminal or the source terminal and the semiconductor layer. The at least one diffusion metal layer provides short-term plasticity in addition to the long-term plasticity provided by the ferroelectric layer. The system further includes a read-write circuit configured to write to each of the one or more cells a value and read back the value based on long-term and short-term plasticity.

### BRIEF DESCRIPTION OF FIGURES

FIG. 1 is a structural schematic of a device known in the prior art, in which polarization and switching of polarization is shown.

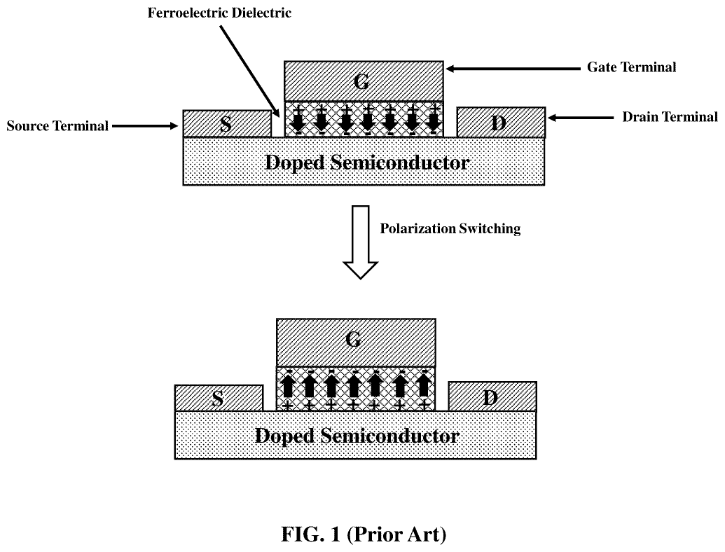

FIG. 2 is a structural schematic of an Integrated Long-& Short-Term Memory (iLSTM) device of the present disclosure according to one embodiment, showing a diffusive metal layer disposed between a drain terminal and a doped semiconductor layer.

FIG. 3 is a similar structural schematic as that shown in FIG. 2 but with an electrically insulating substrate layer.

FIG. 4 is a similar structural schematic as that shown in FIG. 2 but with a diffusive metal layer instead disposed between a source terminal and the doped semiconductor layer.

FIG. 5 is a similar structural schematic as that shown in FIG. 4 but with an electrically insulating substrate layer.

FIG. 6 is a similar structural schematic as that shown in FIG. 2 but with the diffusive metal layer disposed between both the source terminal and the drain terminal and the doped semiconductor layer.

FIG. 7 is a similar structural schematic as that shown in FIG. 6 but with an electrically insulating substrate layer.

FIG. 8 is a schematic of the steps in generating a device, according to one embodiment of the present disclosure.

FIG. 9 provides two graphs (one a conceptual graph of V_{DS} vs. time, one a conceptual graph of I_{D} vs. time).

FIG. 10A is a schematic of a cell according to the present disclosure to demonstrate tunability of the cell, showing tunable resistances (R and R′) and channel length (L_{g}).

FIG. 10B provides graphs, obtained from elsewhere, of voltage in V and current in μA vs. time in ms.

FIG. 10C provides a graph, obtained from elsewhere, of relaxation time in ms vs. 1/R in 1/Kohms showing tunability of diffusive τ by the series resistance (R).

FIG. 10D, FIG. 10E, and FIG. 10F are conceptual drawings showing effects of τ_{decay} modulated by Vₜₕ (FIG. 10D), modulated by V_{GS} (FIG. 10E), and modulated by channel length (FIG. 10F).

FIG. 11A is a conceptual graph of polarization (capacitance per unit area) vs. electric field (voltage divided by thickness of dielectric stack).

FIG. 11B is another conceptual graph of polarization (capacitance per unit area) vs. electric field (voltage divided by thickness of dielectric stack).

FIG. 12A is a conceptual hysteresis curve of I_{D} vs. V_{GS} where V_{GS} is increased to +Vₜₘₐₓ and decreased to −Vₜₘᵢₙ) representing a maximum I_{D} difference on the hysteresis curve.

FIG. 12B provides two sets of graphs (each set including a graph of V_{GS} in volts vs. time and I_{D} in A vs. time) in order to show write and read operations for both the first level (e.g., a one), and the second value (e.g., a zero).

FIG. 12C is an actual I_{D} in μA vs. V_{GS} in volts which shows the hysteresis curve shown conceptually in FIG. 12A for a planar transistor with V_{DS} set at 0.05 V.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel structure that can provide both a long-term memory and a short-term memory in the same device, with interdependencies between such classes of memory is disclosed along with a system and method to use such classes of memory. Towards this end, in the present disclosure, a new memory device that exhibits reconfigurable co-located long-term and short-term memory integrated into a single three or four terminal transistor device is disclosed. The gate is used for controlling the long-term memory and the drain is used for controlling the short-term memory. Analog Memory is encoded to the drain-source current, as discussed below. This novel Integrated Long-& Short-Term Memory (iLSTM) can be configurable by two independent terminals. It should be noted that in the present disclosure the terms iLSTM and DFeFET (Diffusive Ferroelectric Field-Effect Transistor) are used interchangeably and indicate the same structure.

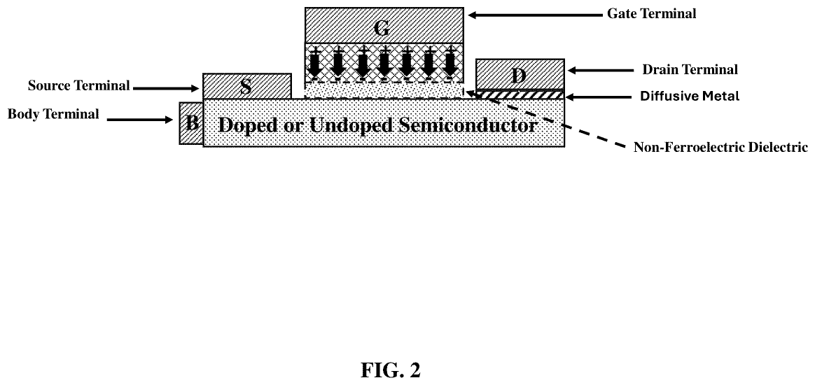

Referring to FIG. 2, a structural schematic of an iLSTM device of the present disclosure according to one embodiment is shown. This embodiment is referred to as a four terminal memory device with Drain interfacial metal (DIM). It should be noted that interfacial metal and diffusive metal are used interchangeably in the present disclosure and are intended to disclose the same structure. This DIM embodiment includes four terminals including a gate terminal, a drain terminal, a source terminal, and a body terminal. The body terminal and the source terminal are coupled to a doped or undoped semiconductor layer which also serves as a substrate. A nonlimiting list of doped (i.e., n-doped or p-doped) and undoped semiconductor layer include doped silicon, silicon carbide (SiC), gallium arsenide (GaAs), gallium nitride (GaN), and indium gallium arsenide (InGaAs), and transition metal oxide (TMO) semiconductors such as, In₂O₃ or doped In₂O₃ (including IGZO, ITO, IWO, IZO), WOₓ, SnO₂ or doped SnO₂ (e.g. Zinc-Tin-Oxide), MoOₓ, CuOₓ, and mono-or multi-layered transition metal dichalcogenide semiconductors such as, MoS₂, MoSe₂, MoTe₂, WS₂, WSe₂, WTe₂ and metal oxychalcogenides such as, Bi₂O₂Se or other suitable materials known to a person having ordinary skill in the art. The terminals may be selected from a wide range of material that provide good connectivity (i.e., low resistance) including polycrystalline silicon (poly). Additionally, the DIM embodiment includes a ferroelectric layer disposed under and coupled to the gate terminal in which polarization switches from one direction to a second direction (either substantially all or partial number of such polarization switches), as described below. Example ferroelectric material includes,

Doped HfO₂ (possible dopants Si, Al, N, La, Gd, Y), HfxZr1-xO₂, Perovskite based Ferroelectrics (ABO₃, where A, B=metal cations), e.g. BaTiO₃, PbTiO₃, PZT-Lead Zirconate Titanate (Solid Solution of PbTiO₃ and PbZrO₃), SrTiO₃, BiFeO₃, Ferroelectric Nitrides (RₓM₁₋ₓN, R=Y, Sc, B, M=Al, Ga, In), e.g. ScAlN, YAlN, BAlN, ScGaN, ScAlGaN

Besides a single layer ferroelectric dielectric material, multi-layered dielectric materials (one ferroelectric and one non-ferroelectric dielectric) may be used as an alternative ferroelectric dielectric to improve channel confinement avoiding charge trapping at the ferroelectric dielectric interface, which is a common mechanism for device failure during cycling. As known to a person having ordinary skill in the art, the channel is the area between drain and the source under the ferroelectric dielectric and the optional non-ferroelectric dielectric through which current flows and which has been described as doped or undoped semiconductor in the DIM embodiment. The DIM embodiment also includes an optional typical non-ferroelectric dielectric layer (e.g., SiO₂) between the ferroelectric layer and the doped or undoped semiconductor layer. For the optional non-ferroelectric dielectric, a high-k interfacial dielectric (e.g. HfO₂) can be incorporated to improve reliability.

If no such optional non-ferroelectric dielectric layer is present, then the ferroelectric layer is connected directly to the doped or undoped semiconductor. Finally, the DIM embodiment includes a novel diffusive metal layer disposed between the drain metal and the doped or undoped semiconductor material layer. The diffusive metal layer allows the device to be used as both a long-term memory and a short-term memory as discussed below. The thickness of the diffusive metal layer is such that no pinholes can be formed (e.g., at least 1 nm). The diffusive metal layer can be a high diffusivity metals such that these metals will have higher diffusivity than common impurities (Carbon) of the underlying doped or undoped semiconductor material (nonlimiting examples of such diffusive metal materials include Cu, Ni, Ag), or high oxygen affinity metals such that these metals will have higher affinity to oxygen than the underlying doped or undoped semiconductor material (non-limiting examples of such materials include Mn, Cr, V, Nb).

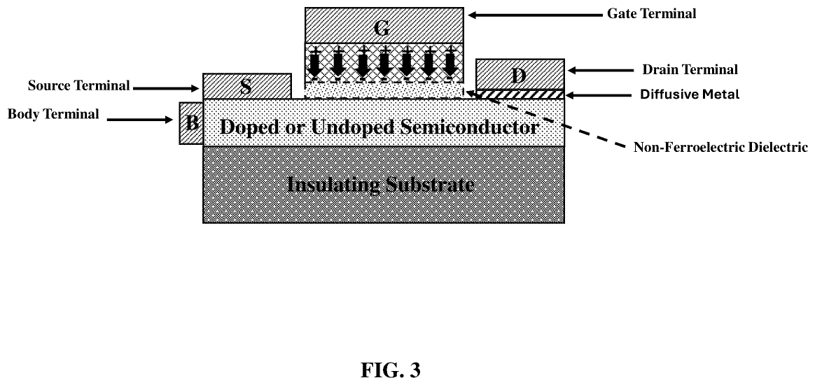

Referring to FIG. 3, a similar structural schematic as that shown in FIG. 2 is provided but this time an electrically insulating substrate layer (e.g., SiO₂ on Si, Sapphire, Quartz, Glass, or other material known to a person having ordinary skill in the art) is disposed under the doped or undoped semiconductor and where the device shown in FIG. 2 is built on top of the substrate layer. Otherwise, FIG. 3 is the same as FIG. 2. The embodiment shown in FIG. 3 is referred to herein as the Drain Interfacial metal Substrate (DIMS).

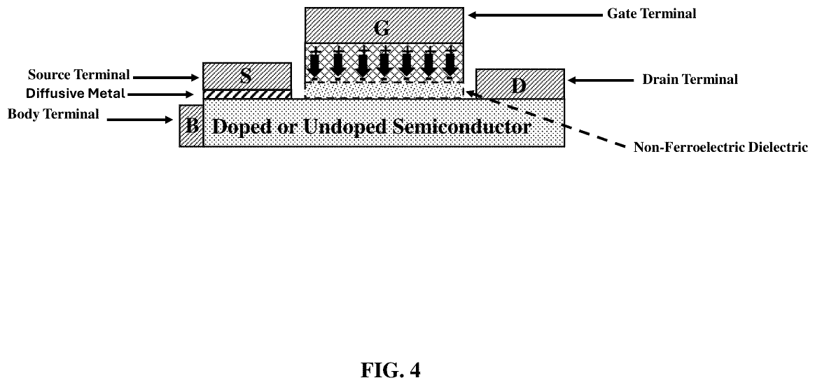

Referring to FIG. 4, a similar structural schematic as that shown in FIG. 2 is provided but this time with the diffusive metal layer instead disposed between the source terminal and the doped or undoped semiconductor. Otherwise, FIG. 4 is the same as FIG. 2. The embodiment shown in FIG. 4 is referred to herein as the Source Interfacial Metal (SIM).

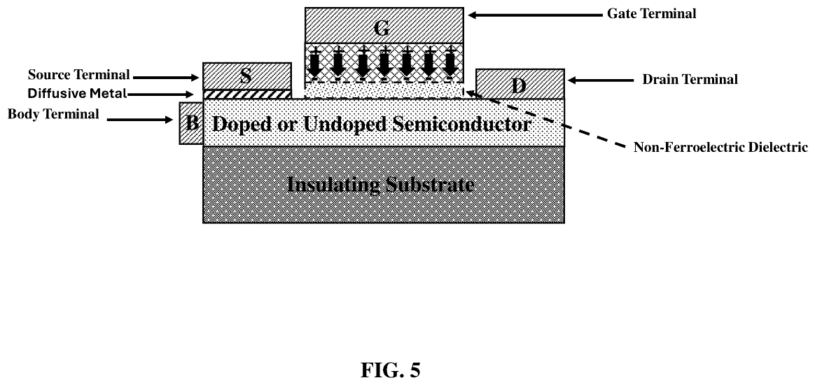

Referring to FIG. 5, a similar structural schematic as that shown in FIG. 4 is provided but this time with the electrically insulating substrate layer (e.g., SiO2 on Si, Sapphire, Quartz, Glass, or other material known to a person having ordinary skill in the art) is disposed under the doped or undoped semiconductor and where the device shown in FIG. 4 is built on top of the substrate layer. Otherwise, FIG. 5 is the same as FIG. 4. The embodiment shown in FIG. 5 is referred to herein as the Source Interfacial Metal Substrate (SIMS).

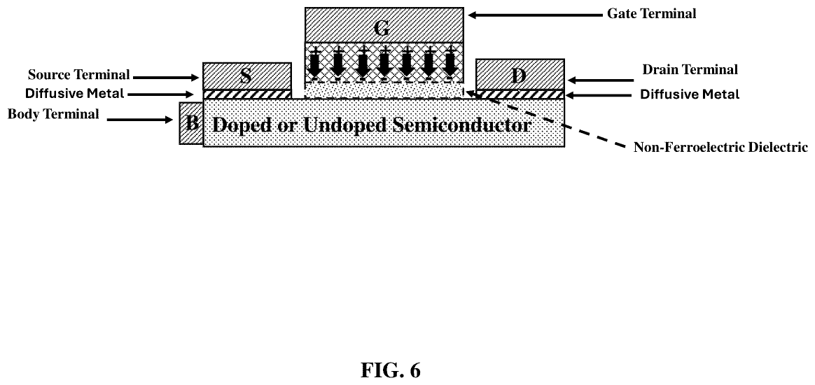

Referring to FIG. 6, a similar structural schematic as that shown in FIG. 2 is provided but this time with the diffusive metal layer disposed between both the source terminal and the drain terminal and the doped or undoped semiconductor. Otherwise, FIG. 6 is the same as FIG. 2. The embodiment shown in FIG. 6 is referred to herein as the Drain Source Interfacial Metal (DSIM).

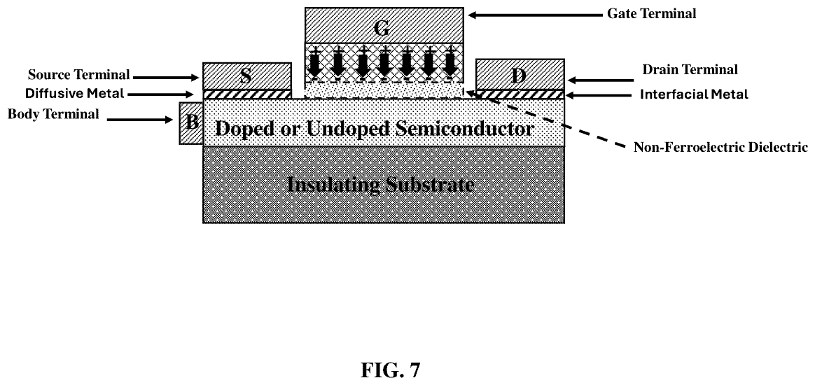

Referring to FIG. 7, a similar structural schematic as that shown in FIG. 6 is provided but this time with the electrically insulating substrate layer (e.g., SiO₂ on Si, Sapphire, Quartz, Glass, or other material known to a person having ordinary skill in the art) is disposed under the doped or undoped semiconductor and where the device shown in FIG. 6 is built on top of the substrate layer. Otherwise, FIG. 7 is the same as FIG. 6. The embodiment shown in FIG. 7 is referred to herein as the Drain Source Interfacial Metal Substrate (DSIMS).

The DIM, DIMS, SIM, SIMS, DSIM, and DSIMS embodiments shown in FIGS. 2-7 are each essentially a typical ferroelectric field effect transistor (FeFET) with ultra-thin channel in the doped or undoped semiconductor layer under the gate terminal. Thickness and dielectric constant of the ferroelectric dielectric and the optional non-ferroelectric dielectric determines the write voltage amplitude needed for switching the gate polarization, hence an ultra-thin thickness is desirable.

The key to design a co-located long-and short-term memory is to design the drain/source contact in a way that would allow a controllable hysteresis response in drain current vs drain voltage (I_{D}-V_{DS}) characteristics where the size of the hysteresis loop will depend on the Max V_{DS}. While this type of hysteresis is detrimental to a device performance as a switch, the hysteresis response is surprisingly advantageous for the long-term/short-term memory interchangeable device. The correct diffusive metal material would allow inter-diffusion of metal ions or oxygen vacancies across the drain/source/both and channel formed about the ferroelectric layer.

The choice of diffusive metal material resulting in highly diffusive yet having lower affinity to oxidation than the channel cation produces counter-clockwise (CCW) hysteresis in the I_{d}-V_{d} response by modulating the channel conductance through metal ion diffusion. The CCW hysteresis is needed for PPF (paired-pulse facilitation), a synaptic feature of the reservoir system. Conversely, using the same metal cation as the channel material (e.g. In for In₂O₃ or ITO channel, W for WOₓ channel) would result in interfacial oxygen scavenging generating an interfacial oxide layer at the drain/channel contact. This effect would produce clockwise (CW) hysteresis in the I_{d}-V_{d} response by modulating the channel conductance through the change in interfacial oxidation level. The CW hysteresis is needed for PPD (paired-pulse depression), the complimentary synaptic feature of the reservoir system. Table 1, below, shows non-limiting example material choices.

TABLE 1
Possible material choice for iLSTM

| | | | Interface | |
|---|---|---|---|---|
| Transistor Channel | S/D Diffusive | S/D Contact | Dielectric | Gate Ferroelectric |
| WO₃ | W, Cu, Ag | Ti/Pt, Pd, | Al₂O₃, HfO₂ | Doped HfO₂ (most common |
| | | Ti/Au | | Hf_{0.5} Zr_{0.5}O₂) |
| In₂O₃ | In, Cu, Ag | Ti/Pt, Pd, | Al₂O₃, HfO₂ | Doped HfO₂ (most common |
| | | Ti/Au | | Hf_{0.5} Zr_{0.5}O₂) |
| SnO₂ | Sn, Cu, Ag | Ti/Pt, Pd, | Al₂O₃, HfO₂ | Doped HfO₂ (most common |
| | | Ti/Au | | Hf_{0.5} Zr_{0.5}O₂) |
| Doped In₂O₃ | Dopant metal, | Ti/Pt, Pd, | Al₂O₃, HfO₂ | Doped HfO₂ (most common |
| | In, Cu, Ag | Ti/Au | | Hf_{0.5} Zr_{0.5}O₂) |
| Doped SnO₂ | Dopant metal, | Ti/Pt, Pd, | Al₂O₃, HfO₂ | Doped HfO₂ (most common |
| | In, Cu, Ag | Ti/Au | | Hf_{0.5} Zr_{0.5}O₂) |
| Multilayer channel | Dopant metal, | Ti/Pt, Pd, | Al₂O₃, HfO₂ | Doped HfO₂ (most common |
| involving In₂O₃(doped | Zn, In, Cu, Ag | Ti/Au | | Hf_{0.5} Zr_{0.5}O₂) |
| or undoped)/ZnO | | | | |

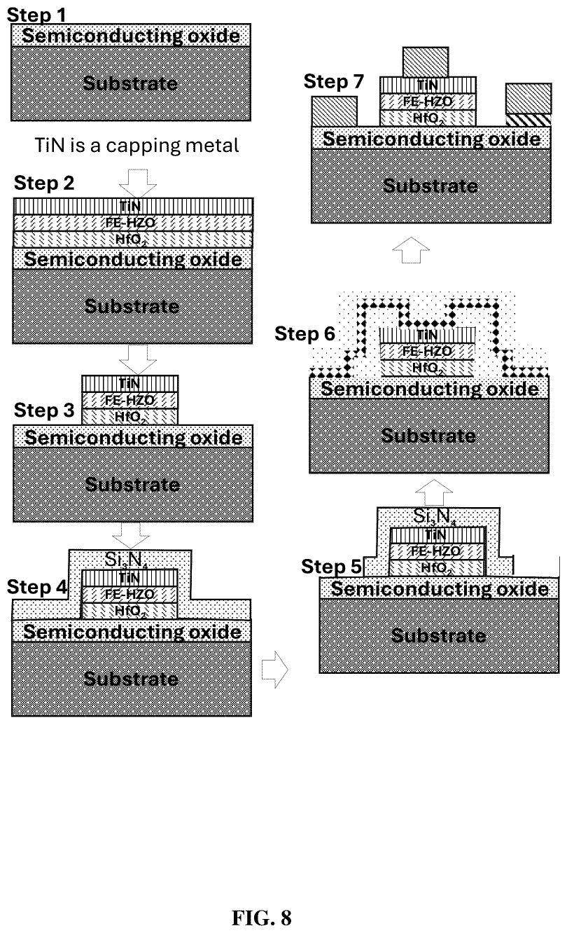

Steps for planar iLSTM fabrication are shown in FIG. 8, which is a schematic of the steps in generating a device, according to one embodiment. Historically metal oxide perovskites such as SrTiO₃ and BiFeO₃ were explored for standalone ferroelectric capacitor memory. These perovskites are not CMOS compatible and require large thickness for FE behavior that precludes them from using as a transistor dielectric. However, ferroelectricity in doped HfO₂ is now known. Doped HfO₂-based FE material can show good ferroelectricity at very low thickness (about 1 nm) making it suitable for low-voltage operation in FeFET. HfO₂ based FE material shows very high polarization switching endurance (10¹¹-10¹² cycles) in a capacitor. However, the number of cycles in a transistor setting is less. This reduction in transistor endurance stems from defect trapping at the FE/interfacial layer (IL) interface in the transistor channel, and from dielectric breakdown of the low-k interfacial layer. For this reason, high-k HfO₂ for IL is used according to the present disclosure. Zr is the most studied dopant to stabilize the ferroelectricity in HfO₂ and Hf_{0.5}Zr_{0.5}O₂ (HZO) has become the most popular FE material for building non-volatile memory transistor. Other potential dopants that includes Al, Si, Gd, La, Y, Sc may be used to optimize the overall transistor performance.

In FIG. 8, there are 7 steps that are outlined in Table 2, below.

TABLE 2
Process steps for fabricating an iLSTM
device (non-limiting example)

| Steps | Process |
|---|---|
| 1 | (i) Low temperature Sputter |
| | (ii) Annealing for defect curing |
| 2 | (i) In-situ ALO growth of Hf0₂/HZO/TiN capping |
| | (ii) Ferroelectric stabilization anneal in N₂ |
| 3 | (i) Lithography to define the gate |
| | (ii) Etching TiN/FE-HZO/Hf0₂ |
| 4 | (i) CVD Grown Si₃N₄ for passivation |
| | (ii) Post-growth annealing (if necessary) |
| 5 | (i) Lithography to define source/gate/drain area |
| | (ii) Etch Si₃N₄ |
| 6 | (i) Thin layer deposition of Diffusive metal (sputtering/ALO) |
| | (ii) Thicker layer deposition of Contact metal (sputtering) |
| 7 | (i) Lithography to define the contacts |
| | (ii) Etch both the contact and diffusive metal |

In operation, the iLSTM device, according to the present disclosure, can be used as a short-term memory or a long-term memory. Each step of the write and read process in each of the above-phases is now described.

### Short-Term Operation

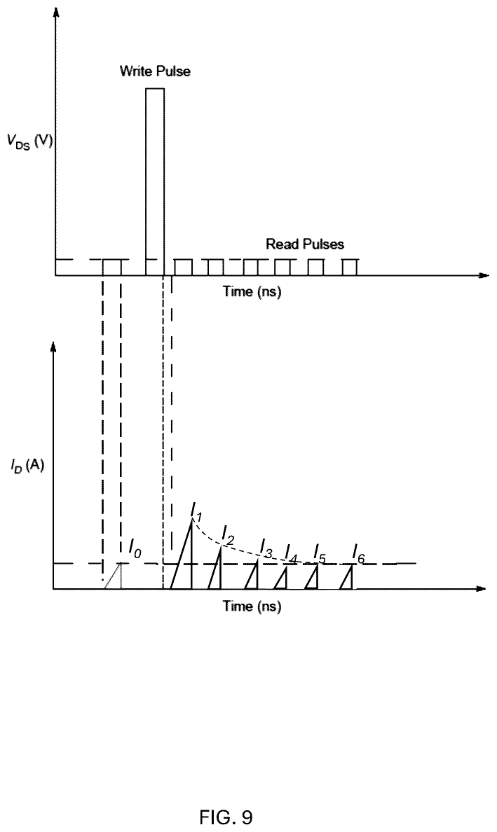

As discussed above, the diffusive metal layer allows the iLSTM to be used additionally for short-term memory. Initially, the write operation is discussed. As an initial matter, threshold voltage of the transistor must be ascertained. The threshold voltage (V_{T}) is determined by applying a predetermined V_{DS} to the drain-source terminals, while sweeping the voltage at the gate from 0 until a predetermined amount of current is sensed passing through the drain terminal (I_{D}), which represents the threshold voltage. It should be noted that the threshold voltage does not change unless the device is used in the long-term memory mode, as discussed below. Once the threshold voltage is determined, then to write to the memory device in the short-term memory mode, a V_{GS} voltage of at least about 1.1*Vₜ and a maximum of V_{DD} (i.e., the supply voltage which represents the technology of the device) is applied while applying a large voltage as V_{DS} (maximum is V_{DD} and minimum is about 0.5*V_{DD}) for at least about 100 ns (the upper limit of pulse duration is determined by application requirements). To read the value now held in the device in the short-term memory mode, a much smaller voltage is applied to the source-drain terminals (V_{DS}) of a minimum of about 0.05*V_{DD} and a maximum of about 0.1*V_{DD}, while maintaining V_{GS} at a minimum of about 1.1*Vₜ and a maximum of V_{DD}. These V_{DS} is applied in a pulse with a short duration of a minimum of 50 ns, where the upper limit is not applicable as decided based on the application of the device. The value of drain current (I_{D}) prior to writing in the read mode is I₀. After writing, the first read I_{D} shortly after writing is I₁ based on application of a read pulse, the second read I_{D} is I₂ based on application of a second read pulse, and so on. After writing a value to the memory, each consecutive read current (I_{D}) is reduced in value until based on a time constant τ it asymptotically reaches back to I₀. A predetermined measure of the time constant τ represents the short term plasticity of the device. This operation is shown in FIG. 9, which represents two graphs (one a conceptual graph of V_{DS} vs. time, one a conceptual graph of I_{D} vs. time).

It should be noted that only a read pulse is chosen such that it only reads the memory without writing. Hence, the read pulse amplitude is substantially lower than the write pulse. Prior to writing, the baseline conductance is ascertained by measuring I₀ using a read pulse. Then after applying a write pulse, a sequence of read pulses are applied to capture the volatile decaying nature of the short-term memory.

As discussed above, the first read pulse following the write pulse will produce the highest current I₁. The increase in I₁ relative to I₀ captures the effect of writing on the conductance. Hence, the strength of short-term plasticity can be measured by (I₁−I₀)/I₀. Another commonly used metric is PPF/PPD (paired-pulse facilitation)/(paired-pulse depression) described further below.

The subsequent read pulses yield gradually lower current until the current returns to baseline current of I₀ which marks the complete decay of the short-term memory. The time difference between the end of the write pulse and the read pulse yielding the baseline current is the τ_{decay} which captures the timescale of short-term memory. A time constant τ is defined based on the decay from the maximum value I₁ to a predetermined reduced value in current.

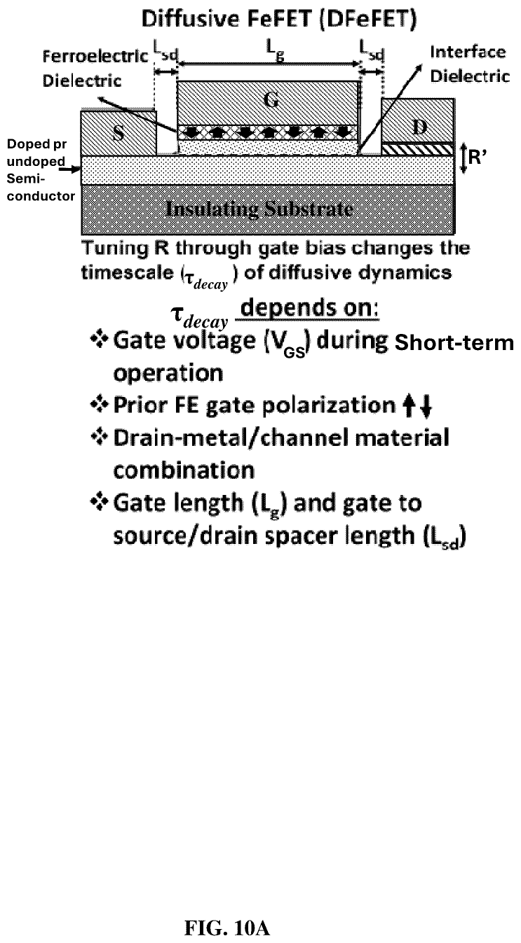

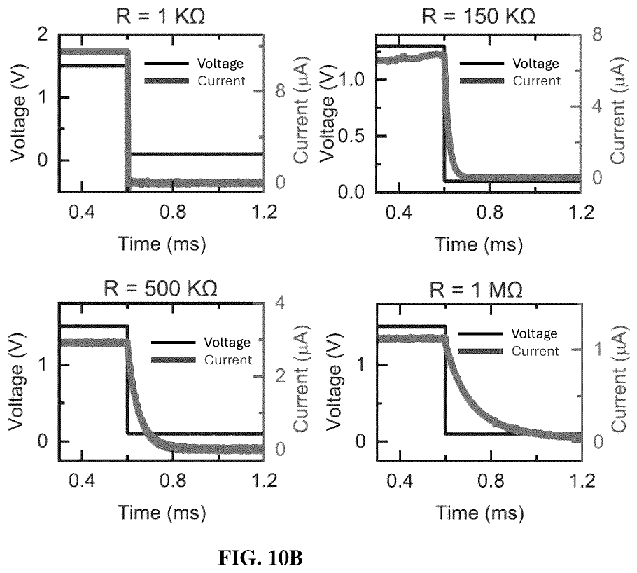

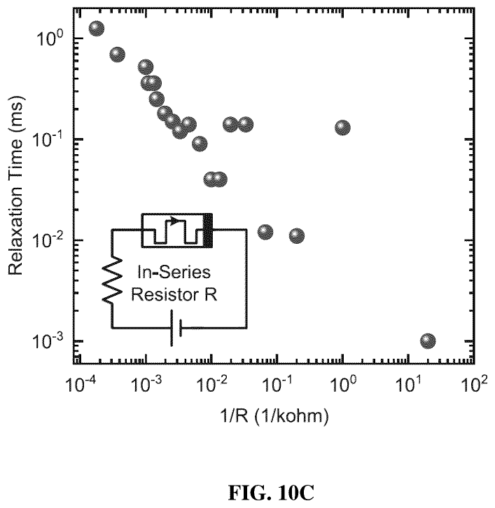

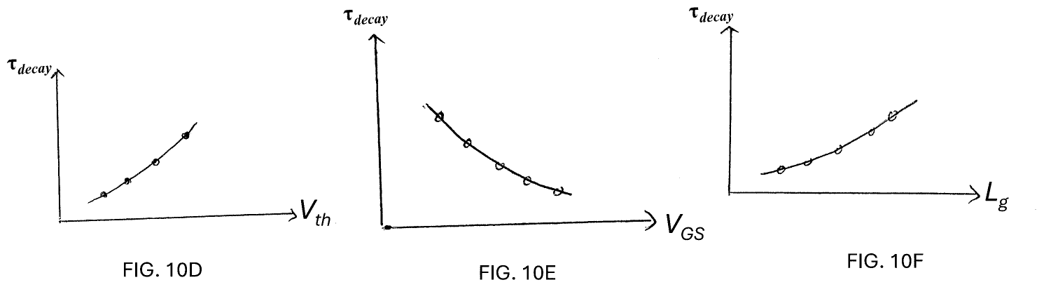

It should be appreciated that the channel is composed of a series combination of channel resistance (tunable “R”) and drain contact resistance R′. R′encodes the volatile short-term memory while R can be tuned by 1) threshold voltage (Vₜₕ) encoding the long-term memory, 2) Gate bias V_{GS}, and 3) gate length, L_{g}. Referring to FIG. 10A, a schematic of a cell according to the present disclosure is provided to demonstrate tunability of the cell, showing tunable R and R′ and L_{g}. The series resistance (R) can be manipulated to vary the time-scale of short-term memory.

FIG. 10B provides graphs, obtained from elsewhere (F. Ye, F. Kiani, Y. Huang, and Q. Xia, “Diffusive memristors with uniform and tunable relaxation time for spike generation in event-based pattern recognition,” Advanced Materials, vol. 35, no. 37, p. 2 204 778, 2023), of voltage in V and current in μA vs. time in ms, while FIG. 10C provides a graph, obtained from elsewhere (see FIG. 10B), of relaxation time in ms vs. 1/R in 1/Kohms showing tunability of diffusive τ by the series resistance (R). It should be noted that Relaxation time in FIG. 10C is the same as τ_{decay}, discussed herein.

Based on the findings shown in FIGS. 10B and 10C, τ_{decay} is proportional to R. That is, by changing the series resistance (R) we can change the time scale of the short-term memory. As a result conceptual drawings are provided showing τ_{decay} VS. Vₜₕ, τ_{decay} VS. V_{GS}, and τ_{decay} VS. L_{g}. These relationships are shown in FIGS. 10D, 10E, and 10F which are conceptual drawings showing effects of τ_{decay} modulated by Vₜₕ (FIG. 10D), modulated by V_{GS} (FIG. 10E), and modulated by channel length (FIG. 10F).

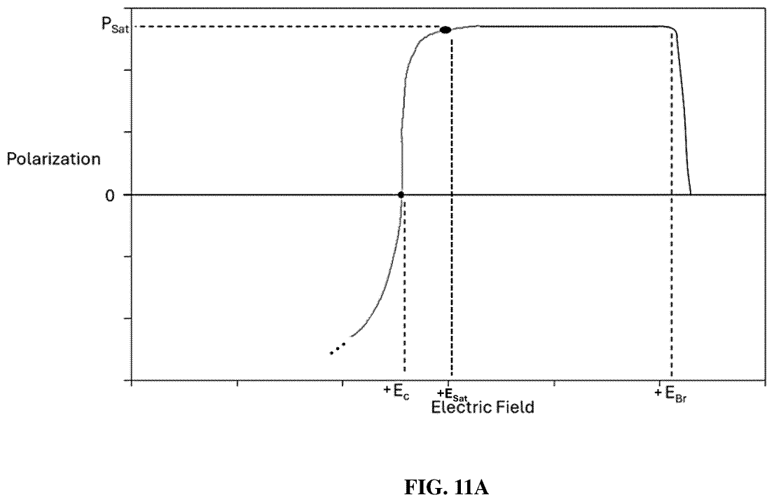

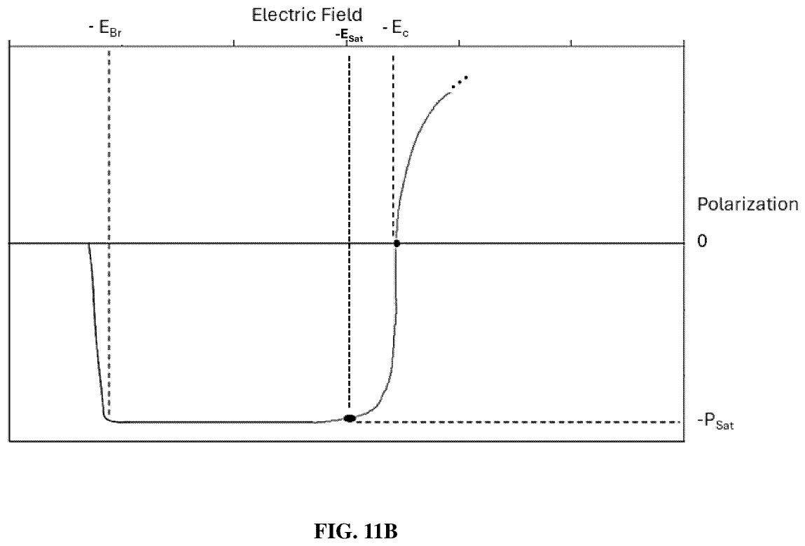

Next is the operation of the device in the long-term memory mode. In this mode, as an initial matter an electric field which is defined as voltage (i.e., V_{GS}) divided by thickness (i.e., the thickness of the ferroelectric dielectric and the optional non-ferroelectric dielectric) that is referred to as a coercive field is ascertained. The coercive field is the field that polarization begins to change from a first polarization to a second and opposite polarization. Polarization is measured in capacitance per unit area, which can be measured by a number of laboratory equipment, known to a person having ordinary skill in the art. The polarization may start at a negative value and rise as the electric field increases until the polarization crosses the x-axis (i.e., polarization=0). This level of electric field is referred to as the coercive field (+E_{C}). As the electric field continues to increase the polarization increases but reaches a plateau, referred to herein as the +P_{Sat}, which refers to a polarization that is all substantially in the same direction. This level of polarization occurs at an electric field value that is referred to as +E_{Sat}. As the electric field continues to increase, at some point the polarization suddenly changes and drops to zero which signifies the breakdown field (referred to as the +E_{Br}). This behavior is shown in FIG. 11A, which is a conceptual graph of polarization (capacitance per unit area) vs. electric field (voltage divided by thickness of dielectric stack).

Alternatively, the polarization may start at a positive value and lower as the electric field decreases until the polarization crosses the x-axis (i.e., polarization=0). This level of electric field is referred to as the coercive field (−E_{C}). As the electric field continues to decrease in the negative direction, the polarization decreases but reaches a plateau, referred to herein as the −P_{Sat}. This level of polarization occurs at an electric field value that is referred to as −E_{Sat}. As the electric field continues to increase, at some point the polarization suddenly changes and increases to zero which signifies the breakdown field (referred to as the −E_{Br}). This behavior is shown in FIG. 11B, which similar to FIG. 11A is another conceptual graph of polarization (capacitance per unit area) vs. electric field (voltage divided by thickness of dielectric stack). As discussed above, at −E_{C}, the polarization begins to switch.

It should be noted that a coercive voltage (i.e., +V_{C} or −V_{C}) is defined as coercive field (i.e., +E_{C} or (−E_{C}) multiplied by the thickness of the dielectric stack. These coercive voltages represent minimum voltage at which polarization begins to switch.

Similarly, it should be noted that maximum threshold voltage of the transistor (a parameter that in a transistor typically remains the same but in the ferroelectric device of the present disclosure it changes based on polarization), +Vₜₘₐₓ and −Vₜₘᵢₙ are determined based on saturation fields (i.e., +E_{Sat} and −E_{Sat}) multiplied by the thickness of the dielectric stack.

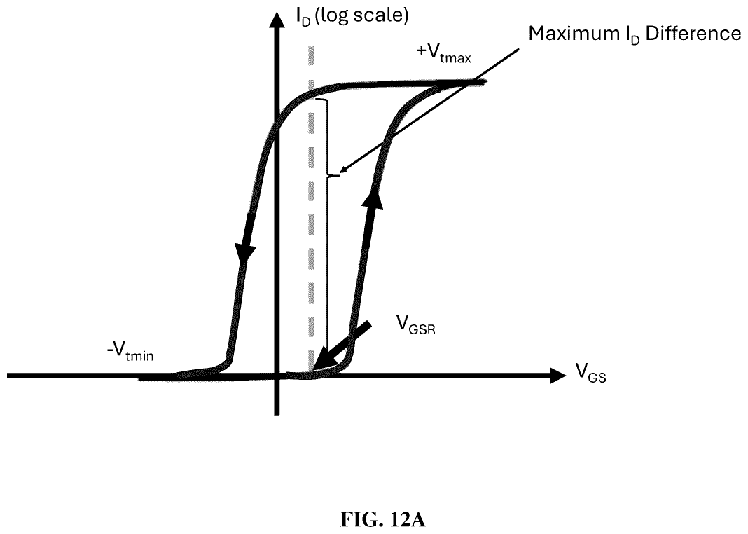

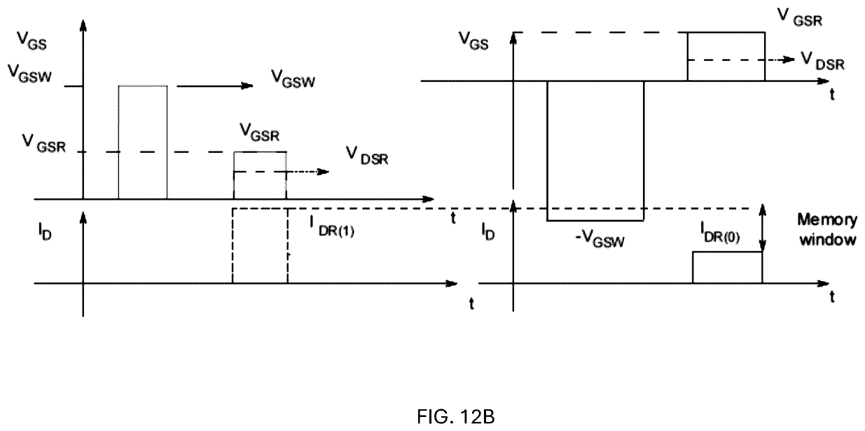

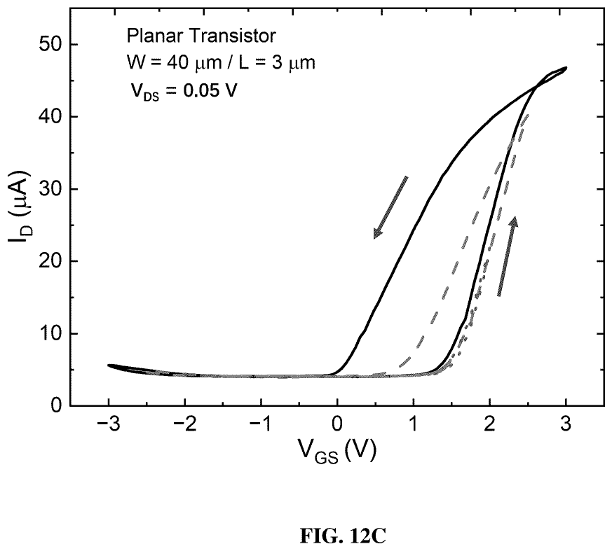

The write and read operations of the long-term memory are now discussed. The write operation is discussed first. As an initial matter, threshold voltage (+Vₜₘₐₓ and −Vₜₘᵢₙ) of the transistor must be ascertained. This can be done by performing a sweep of V_{GS} voltages while measuring capacitance per unit area, as discussed above. Once the threshold voltages (+Vₜₘₐₓ and −Vₜₘᵢₙ) are determined, then to write to the memory device in the long-term memory mode based on a 2-level memory (i.e., 0s and 1s), a V_{GS} voltage of at least 1* to about 1.1* threshold voltages (+Vₜₘₐₓ and −Vₜₘᵢₙ) is applied with a maximum of about 0.5* the breakdown voltage (positive breakdown voltage +V_{Br} or negative breakdown voltage, −V_{Br}) in the form of a pulse with a minimum duration of about 100 ns and a maximum duration that is dependent on the application, while maintaining V_{DS} at zero. To read the value now held in the device in the long-term memory mode, a much smaller voltage is applied to the source-drain terminals (V_{DS}) of a minimum of about 0.05*V_{DD} and a maximum of about 0.1*V_{DD}, while maintaining V_{GS} at about V_{GSR}. V_{GSR} is determined by finding the V_{GS} on a combination of I_{D} vs. V_{GS} hysteresis curves (see FIGS. 11A and 11B, converted to I_{D} vs. V_{GS} shown in FIG. 12A which is a hysteresis curve of I_{D} vs. V_{GS} where V_{GS} is increased to +Vₜₘₐₓ and decreased to −Vₜₘᵢₙ) that corresponds to the maximum I_{D} difference on the hysteresis curve. FIG. 12A is based on application of a small V_{DS} of a minimum of about 0.05*V_{DD} and a maximum of about 0.1*V_{DD} while sweeping the V_{GS} starting from 0 to +Vₜₘₐₓ to −Vₜₘₐₓ to 0. This sweeping is done to determine the maximum memory window and the read voltage (the VGS where the ID hysteresis between the positive and the negative sweep is the highest). During the actual read the VGS pulse equal to the read voltage is applied. The V_{GS} is applied in a pulse form with a short duration of a minimum of 50 ns, where the upper limit is not applicable as decided based on the application of the device. The value of drain current (I_{D}) is measured which is a positive pulse current to determine the value held in the long-term memory. If the value is a first level (e.g., referring to a one), then the drain current for application of a positive V_{GS} would be above a first predetermined threshold. If the measured I_{D} is below a second threshold after applying a positive V_{GS}, then the value held in the memory refers to a second level (e.g., a zero).

Referring to FIG. 12B two sets of graphs (each set including a graph of V_{GS} in volts vs. time and I_{D} in A vs. time) in order to show write and read operations for both the first level (e.g., a one), and the second value (e.g., a zero).

The memory can be operated based on a long-term memory but for multi-levels (e.g., instead of just two level, i.e., 0s and 1s, based on four levels). In order to achieve this goal, intermediate levels of polarization may be achieved. That is, instead of a minimum V_{GS} of between about 1* to about 1.1* of the threshold voltage (+Vₜₘₐₓ and −Vₜₘᵢₙ), an intermediate value between coercive voltage (+V_{C} and −V_{C}) and threshold voltage (+Vₜₘₐₓ and −Vₜₘᵢₙ) for example (((+Vₜₘₐₓ)—(+V_{C}))/2) or ((−V_{C})−(−Vₜₘᵢₙ)/2)) may be used to write multi-level data. Accordingly, by maintaining V_{GS} at about V_{GSR} (see above and FIG. 12A for how to determine V_{GSR}), I_{D} can be read at different levels associated with each level of the multi-level memory.

Referring to FIG. 12C, which is an actual I_{D} in μA vs. V_{GS} in volts shows the hysteresis curve shown conceptually in FIG. 12A for a planar ferroelectric transistor with V_{DS} set at 0.05 V. Different curves represent different V_{GS}-sweeping maximum. Higher V_{GS}-sweeping maximum shows higher hysteresis. This suggests that ferroelectric memory is capable of having multi-level long-term memory.

Those having ordinary skill in the art will recognize that numerous modifications can be made to the specific implementations described above. The implementations should not be limited to the particular limitations described. Other implementations may be possible.

1. A cell capable of having long-term and short-term plasticity, comprising:
a source terminal, a drain terminal, and a gate terminal each coupled to a semiconductor layer, wherein the semiconductor layer is a doped semiconductor layer or an undoped semiconductor layer;
a ferroelectric dielectric layer disposed between the gate terminal and the semiconductor layer; and
at least one diffusion metal layer disposed between the drain terminal or the source terminal and the semiconductor layer,
wherein the at least one diffusion metal layer provides short-term plasticity in addition to the long-term plasticity provided by the ferroelectric layer.

2. The cell of claim 1, wherein the semiconductor layer is connected to a body terminal.

3. The cell of claim 2, wherein the semiconductor layer is disposed on an electrically isolating substate.

4. The cell of claim 1, wherein the at least one diffusion metal layer includes a first diffusion metal layer disposed between the drain terminal and the semiconductor layer and a second diffusion metal layer disposed between the source terminal and the semiconductor layer.

5. The cell of claim 4, wherein the semiconductor layer is connected to a body terminal.

6. The cell of claim 5, wherein the semiconductor layer is disposed on an electrically isolating substate.

7. A system for short-term and long-term plasticity, comprising:
one or more cells, each capable of having long-term and short-term plasticity, each of the one or more cells, comprising:
a source terminal, a drain terminal, and a gate terminal each coupled to a semiconductor layer, wherein the semiconductor layer is a doped semiconductor layer or an undoped semiconductor layer;
a ferroelectric dielectric layer disposed between the gate terminal and the semiconductor layer; and
at least one diffusion metal layer disposed between the drain terminal or the source terminal and the semiconductor layer,
wherein the at least one diffusion metal layer provides short-term plasticity in addition to the long-term plasticity provided by the ferroelectric layer; and
a read-write circuit configured to write to each of the one or more cells a value and read back the value based on long-term and short-term plasticity.

8. The system of claim 7, wherein the read-write circuit includes one or more amplifiers to amplify a sense current corresponding to current passing through the drain terminal (I_{D}) when a first voltage is applied across the gate-source terminals (V_{GS}) and a second voltage is applied across drain-source terminals (V_{DS}).

9. The system of claim 8, wherein for short-term memory plasticity, the read-write circuit is configured to:
apply a predetermined V_{DS} while sweeping V_{GS} until a threshold voltage (Vₜ) corresponds to a predetermined sensed I_{D}.

10. The system of claim 9, wherein the read-write circuit for a write operation for short-term plasticity is configured to:
apply a voltage between V_{DD} and about 0.5*V_{DD} as V_{DS},
apply a voltage pulse between 0 V and a minimum of about 1.1*Vₜ and a maximum of V_{DD} as V_{GS}, wherein the voltage pulse has a minimum duration of about 100 ns, and remove both V_{DS} and V_{GS},
wherein V_{DD} corresponds to operational voltage of the one or more cells.

11. The system of claim 10, wherein the read-write circuit for a read operation for short-term plasticity is configured to:
apply a series of voltage pulses between 0 v and a minimum of about 0.05*V_{DD} and a maximum of about 0.1*V_{DD} as V_{DS}, wherein each pulse in the series of the voltage pulses has a minimum duration of about 50 ns,
apply a constant voltage of a minimum of about 1.1*Vₜ and a maximum of V_{DD} as V_{GS},
using a sensing resistor measure I_{D} during each pulse of the series of pulses, and
measure a time constant (τ) representing decay in I_{D} from a maximum level until decayed to a predetermined level, wherein the τ represents the short-term plasticity.

12. The system of claim 8, wherein for long-term memory plasticity, the read-write circuit is configured to:
apply a predetermined voltage as V_{DS} while sweeping an electric field applied to the gate terminal until positive and negative polarization saturation are achieved thus corresponding to maximum and minimum threshold voltages (+Vₜₘₐₓ and −Vₜₘᵢₙ).

13. The system of claim 12, wherein polarization is determined by measuring capacitance under the gate terminal per unit area.

14. The system of claim 12, wherein the +Vₜₘₐₓ and −Vₜₘᵢₙ are determined by multiplying the applied electric field at the positive and negative polarization saturation by thickness of material between the gate terminal and the semiconductor layer.

15. The system of claim 14, breakdown electric field and thus breakdown voltages (+V_{Br} and −V_{Br}) of the one or more cells is determined by continuing sweeping the electric field applied to the gate terminal until breakdown occurs.

16. The system of claim 15, wherein the read-write circuit for a read operation for long-term plasticity is configured to:
determine V_{GSR} as the read voltage for said long-term plasticity by:
establish a hysteresis curve of I_{D} vs. V_{GS} by sweeping V_{GS} between +Vₜₘₐₓ and −Vₜₘᵢₙ and measuring I_{D}, wherein V_{GSR} represents a V_{GS} corresponding to a maximum I_{D} across said hysteresis curve.

17. The system of claim 16, wherein the read-write circuit for a write operation for a 2-level long-term plasticity is configured to:
apply a voltage pulse of a minimum duration of 100 ns as V_{GS} between 0 V and a minimum of 1* to about 1.1* maximum or minimum threshold voltages (+Vₜₘₐₓ or −Vₜₘᵢₙ) and a maximum of about 0.5* breakdown voltage (+V_{Br} and −V_{Br}), wherein accordingly a positive V_{GS} corresponds to a substantially uniform polarization in a first direction, and a negative V_{GS} corresponds to a substantially uniform polarization in a second direction opposite the first direction.

18. The system of claim 17, wherein the read-write circuit for a read operation for a 2-level long-term plasticity is configured to:
apply a read pulse voltage of a minimum duration of 50 ns as V_{DS} between 0 V and a minimum of about 0.05*V_{DD} and maximum of about 0.1*V_{DD}, and
apply a read voltage of about V_{GSR} as V_{GS},
measure I_{D},
if I_{D} is above a first predetermined threshold, then the read value corresponds to a first value,
if I_{D} is below a second predetermined threshold, then the read value corresponds to a second value.

19. The system of claim 16, wherein the read-write circuit for a write operation for a multi-level long-term plasticity is configured to:
apply a voltage pulse of a minimum duration of 100 ns as V_{GS} between 0 V and a minimum of 1* to about 1.1* (+Vₜₘₐₓ)/m or (−Vₜₘᵢₙ)/m, where m represents the number of levels, wherein accordingly a positive V_{GS} corresponds to a majority polarization in a first direction, and a negative V_{GS} corresponds to a majority polarization in a second direction opposite the first direction.

20. The system of claim 19, wherein the read-write circuit for a read operation for a multi-level long-term plasticity is configured to:
apply a read pulse voltage of a minimum duration of 50 ns as V_{DS} between 0 V and a minimum of about 0.05*V_{DD} and maximum of about 0.1*V_{DD}, and
apply a read voltage of about V_{GSR} as V_{GS},
measure I_{D},
if I_{D} is between predetermined thresholds Iₙ and Iₙ₋₁ then the read value corresponds to an n value, wherein 1≤n≤m−1.
